(19) United States
(12) Patent Application Publication
(10) Pub. No.: US 2005/0088818 A1
(43) Pub. Date: Apr. 28, 2005

(54) Backflow-preventive fan module

(75) Inventor: Yi-Lung Chou, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 10/742,820

(22) Filed: Dec. 23, 2003

(30) Foreign Application Priority Data
Oct. 23, 2003 (TW) 092218842

(51) Int. Cl. H05K 7/20

(52) U.S. Cl. 361/695

(57) ABSTRACT

A backflow-preventive fan module includes a partition member separating a housing into two separated receiving chambers and two air outlets, two fan modules respectively mounted in the receiving chambers, and two backflow prevention members respectively mounted in the receiving chambers adjacent to the two air outlets. When one fan assembly failed, the corresponding backflow prevention member is forced by pressure difference to block the corresponding air outlet, and the other fan assembly functions normally to effectively dissipate heat out of the computer in which the fan module is installed.

### BACKGROUND OF THE INVENTION

1. Field of the Invention

The present invention relates to a fan module and, more particularly, to a backflow-preventive fan module practical for use in a computer to dissipate heat.

2. Description of Related Art

When designing a computer, heat dissipation problem may bother the development engineers. More particularly, a CPU of relatively higher clock frequency produces relatively greater thermal energy. If heat is not effectively dissipated during the operation of the CPU, the computer may fails quickly. Therefore, it is necessary to install heat dissipating devices in a computer.

Various backflow-preventive fan modules have been disclosed for use in a computer to dissipate heat. A regular backflow-preventive fan module generally comprises a housing, a fan assembly mounted inside the housing and adapted to induce currents of air to carry heat out of the computer in which the housing is installed, and a backflow preventor adapted to prevent reverse flow of air into the inside of the computer.

Conventional fan modules with backflow prevention means are still not satisfactory in function. U.S. Pat. No. 5,890,959 discloses a fan module having a backflow preventor. According to this design, the backflow preventor is complicated and comprised of a number of parts, resulting in high manufacturing cost. U.S. Pat. No. 5,793,610 discloses a cooling fan system having means to prevent backflow. According to this design, the maintenance engineer must turn off the computer before starting the repair work when one element of the backflow prevention means damaged. U.S. Pat. No. 5,438,226 discloses an apparatus for redundant cooling of electronic devices. According to this design, the flowing direction of air is disturbed when one of the air movers failed. U.S. Pat. No. 6,217,440B1 discloses an Air mover system with reduced reverse air flow. According to this design, each of the air movers includes means for preventing reverse rotation of the air flow generating means, thereby reducing reverse air flow. Because these air movers are specially designed, commercially available air movers cannot be used as a substitute.

### SUMMARY OF THE INVENTION

The present invention has been accomplished under the circumstances in view. It is therefore the main object of the present invention to provide a backflow-preventive fan module, which functions normally to effectively dissipate heat from the computer when either of the fan assemblies failed. It is another object of the present invention to provide a backflow-preventive fan module, which use many common parts to reduce the cost. To achieve these and other objects of the present invention, the backflow-preventive fan module is comprised of a housing, a S-shaped partition device, two fan assemblies, a first backflow prevention member, and a second backflow prevention member. The housing is mounted inside a case of a computer, comprising a hot air dissipation opening facing and in air communication with the outside of the case of the computer, a bottom panel, a first air inlet in the bottom panel, and a second air inlet in the bottom panel. The S-shaped partition device mounted in the housing and divided the internal space of the housing into a first receiving chamber and a second receiving chamber, having an end extended to the hot air dissipation opening to separate the hot air dissipation opening into a first air outlet and a second air outlet. The first receiving chamber is disposed in air communication between the first air inlet and the first air outlet. The second receiving chamber is disposed in air communication between the second air inlet and the second air outlet. The two fan assemblies are respectively mounted in the first receiving chamber and the second receiving chamber. The first backflow prevention member is mounted in the first receiving chamber adjacent to the first air outlet. The second backflow prevention member is mounted in the second receiving chamber adjacent to the second air outlet.

During heat dissipation operation of the computer, the two fan assemblies are operated to suck hot air from the computer into the first and second air inlets, and then to blow the intake flows of hot air to the outside of the computer, and at the same time, the first backflow prevention member and the second backflow prevention member are opened from the first air outlet and the second air outlet respectively by the respective flows of air for quick dissipation of hot air out of the computer.

According to the present invention, the S-shaped partition device divides the internal space of the housing into the two independent receiving chambers, the two fan assemblies are respectively mounted in the first and second receiving chambers, and the backflow prevention members are mounted in the first and second receiving chambers adjacent to the first air outlet and the second air outlet respectively. Therefore, when one fan assembly failed, the corresponding first backflow prevention member is automatically forced by the pressure difference between the inside and the outside of the housing to block the corresponding first air outlet, preventing backflow of air into the inside of the housing through the corresponding first air outlet. At the same time, the other fan assembly functions normally, and hot air is continuously dissipated out of the housing into the open space outside the computer.

Further, because various parts used in the backflow-preventive fan module are common parts, for example, the fan assemblies, the S-shaped partition device, the backflow prevention members, the structural design of the present invention is simplified, and the manufacturing cost is relatively reduced.

Other objects, advantages, and novel features of the invention will become more apparent from the following detailed description when taken in conjunction with the accompanying drawings.

### BRIEF DESCRIPTION OF THE DRAWINGS

FIG. 1 is a schematic drawing showing an application example of the present invention.

FIG. 2 is an exploded view of the backflow-preventive fan module according to the present invention.

FIG. 3 is a top view of the backflow-preventive fan module according to the present invention.

### DETAILED DESCRIPTION OF THE PREFERRED EMBODIMENT

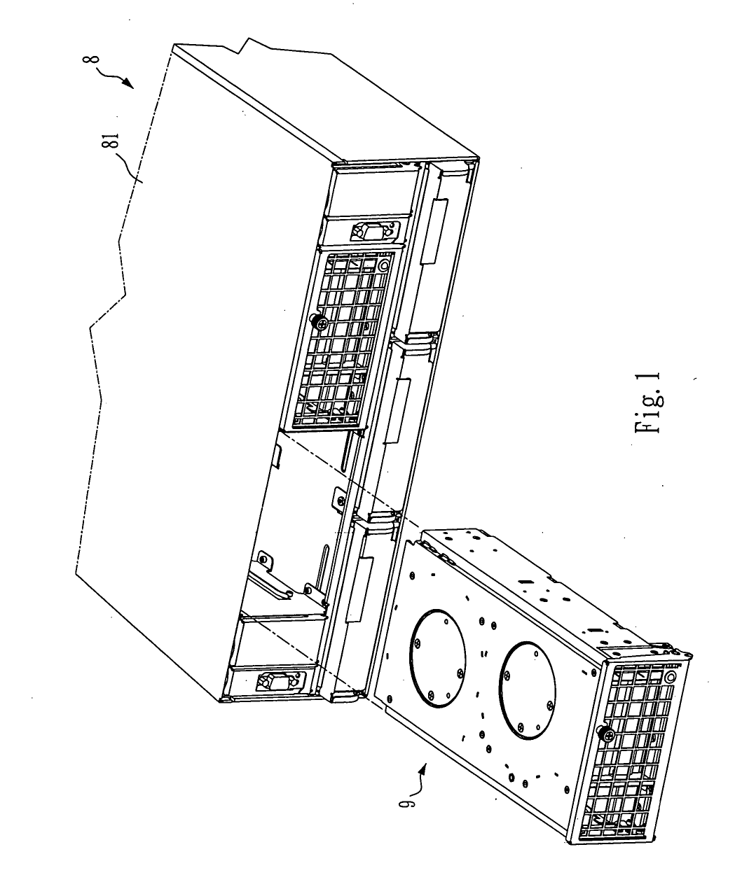

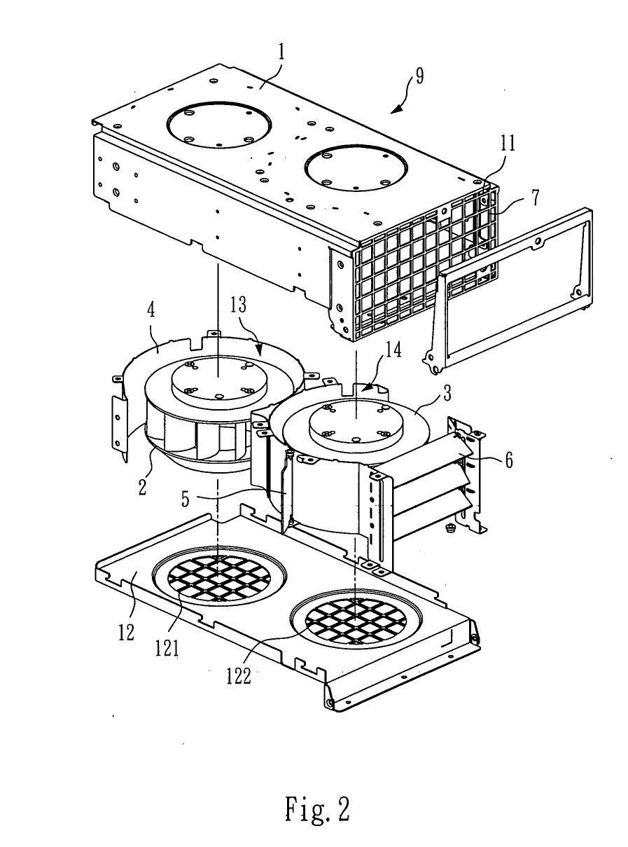

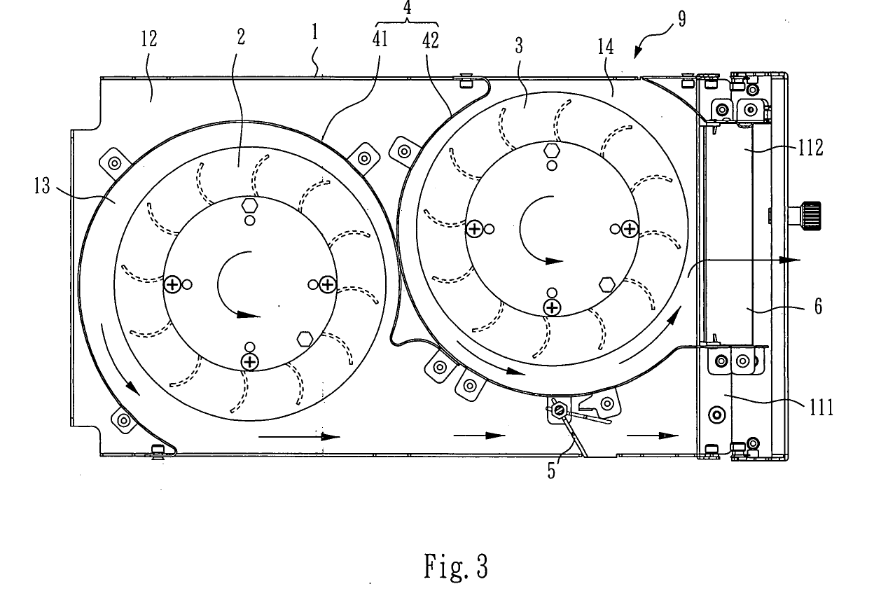

Referring to FIGS. 1-3, a backflow-preventive fan module 9 in accordance with the present invention is shown comprising a housing 1, a S-shaped partition device 4, two fan assemblies 2 and 3, a first backflow prevention member 5, and a second backflow prevention member 6.

The housing 1 is mounted inside a case 81 of a computer 8, having a hot air dissipation opening 11 facing and in air communication with the outside of the case 81 of the computer 8, a grille mask 7 covering outside the hot air dissipation opening 11 to stop external bodies from entering the housing 1, a bottom panel 12, and a first air inlet 121 and a second air inlet 122 in the bottom panel 12.

The S-shaped partition device 4 comprises a first partition member 41 and a second partition member 42. The first partition member 41 and the second partition member 42 have a substantially smoothly arched configuration, and are connected together to form a substantially S-shaped partition structure. The partition device 4 is mounted inside the housing 1, dividing the internal space of the housing 1 into a first receiving chamber 13 and a second receiving chamber 14. The S-shaped partition device 4 has an end extended to the hot air dissipation opening 11, separating the hot air dissipation opening 11 into a first air outlet 111 and a second air outlet 112. The first receiving chamber 13 is in air communication between the first air inlet 121 and the first air outlet 111. The second receiving chamber 14 is in air communication between the second air inlet 122 and the second air outlet 112.

The two fan assemblies 2 and 3 according to the present preferred embodiment are axial-flow fans. Other equivalent fan assemblies, for example, centrifugal fans may be used as a substitute. The two fan assemblies 2 and 3 are respectively mounted inside the first receiving chamber 13 and the second receiving chamber 14. The first backflow prevention member 5 is mounted in the first receiving chamber 13 of the housing 1 adjacent to and blocking the first air outlet 111. The second backflow prevention member 6 is mounted in the second receiving chamber 14 of the housing 1 adjacent to and blocking the second air outlet 112.

According to the present preferred embodiment, the first backflow prevention member 5 is a one-way valve directly pivoted to the bottom panel 12 of the housing 1, and the second backflow prevention member 6 is a shutter horizontally pivoted to the second air outlet 112.

During heat dissipation operation of the computer 8, the two fan assemblies 2 and 3 are operated to suck hot air from the computer 8 into the first and second air inlets 121 and 122. At this time, the S-shaped partition device 4 separates the air flows induced by the fan assemblies 2 and 3, and guides the air flows in different directions to the outside of the case 81 of the computer 8 via the first air outlet 111 and the second air outlet 112 respectively. During operation of the fan assemblies 2 and 3, the first backflow prevention member 5 and the second backflow prevention member 6 are opened from the first air outlet 111 and the second air outlet 112 respectively by the respective flows of air for quick dissipation of hot air out of the computer 8.

As indicated above, the S-shaped partition device 4 divides the internal space of the housing 1 into the two independent receiving chambers 13 and 14, the fan assemblies 2 and 3 are respectively mounted in the first and second receiving chambers 13 and 14, and the backflow prevention members 5 and 6 are mounted in the first and second receiving chambers 13 and 14 adjacent to the first air outlet Ill and the second air outlet 112 respectively. Therefore, when one fan assembly 2 failed, the corresponding first backflow prevention member (one-way valve) 5 is automatically forced by the pressure difference between the inside and the outside of the housing 1 to block the corresponding first air outlet 111, preventing backflow of air into the inside of the housing 1 through the corresponding first air outlet 111. At the same time, the other fan assembly 3 functions normally, and hot air is continuously dissipated out of the housing 1 into the open space outside the computer 8. Return spring means (not shown) may be used to automatically return the first backflow prevention member 5 to the close position.

On the contrary, when the other fan assembly 3 failed, the corresponding second backflow prevention member 6 (shutter) is forced by its gravity weight and the pressure difference between the inside and the outside of the housing 1 to block the corresponding second air outlet 112, preventing backflow of air into the inside of the housing 1 through the corresponding second air outlet 112. At the same time, the other fan assembly 2 functions normally, and hot air is continuously dissipated out of the housing 1 into the open space outside the computer 8. By means of the aforesaid structural design, the backflow-preventive fan module keeps dissipating heat from the computer stably even one of the fan assemblies 2 and 3 failed.

Further, because various parts used in the backflow-preventive fan module are common parts, for example, the fan assemblies 2 and 3, the S-shaped partition device 4, the backflow prevention members 5 and 6, the structural design of the present invention is simplified, and the manufacturing cost is relatively reduced.

The first and second backflow prevention members 5 and 6 may be pivoted to the housing 1 by pivots and pivot holes. Preferably, the first and second backflow prevention members 5 and 6 are molded from flexible materials such as rubber, plastics, resin, or the like. When damaged, the damaged backflow prevention member can be deformed and easily be removed from the housing 1 for a replacement.

A prototype of backflow-preventive fan module has been constructed with the features of FIGS. 1˜3. The backflow-preventive fan module functions smoothly to provide all of the features discussed earlier.

Although a particular embodiment of the present invention has been described in detail for purposes of illustration, various modifications and enhancements may be made without departing from the spirit and scope of the invention. Accordingly, the invention is not to be limited except as by the appended claims.

1. A backflow-preventive fan module comprising:
a housing mounted inside a case of a computer, said housing comprising a hot air dissipation opening facing and in air communication with the outside of the case of said computer, a bottom panel, a first air inlet in said bottom panel, and a second air inlet in said bottom panel;
a S-shaped partition device mounted in said housing and dividing the internal space of said housing into a first receiving chamber and a second receiving chamber, said S-shaped partition device having an end extended to said hot air dissipation opening to separate said hot air dissipation opening into a first air outlet and a second air outlet, said first receiving chamber being disposed in air communication between said first air inlet and said first air outlet, said second receiving chamber being disposed in air communication between said second air inlet and said second air outlet;
two fan assemblies respectively mounted in said first receiving chamber and said second receiving chamber;
a first backflow prevention member mounted in said first receiving chamber adjacent to said first air outlet; and
a second backflow prevention member mounted in said second receiving chamber adjacent to said second air outlet.

2. The backflow-preventive fan module as claimed in claim 1, wherein said fan assemblies are axial-flow fans.

3. The backflow preventive fan module as claimed in claim 1, wherein said fan assemblies are centrifugal fans.

4. The backflow preventive fan module as claimed in claim 1, wherein said first backflow prevention member is a one-way valve.

5. The backflow preventive fan module as claimed in claim 1, wherein said second backflow prevention member is a shutter covering said second air outlet.

6. The backflow preventive fan module as claimed in claim 1, wherein said first backflow prevention member and said second backflow prevention member are respectively made of flexible materials.

7. The backflow preventive fan module as claimed in claim 1, wherein said housing further comprises a grille mask covering outside said hot air dissipation opening.
